(19) United States
(12) Patent Application Publication
(10) Pub. No.: US 2012/0199178 A1
(43) Pub. Date: Aug. 9, 2012

(54) RAW MODULE FOR PRODUCING A THIN-FILM SOLAR MODULE, AND THIN-FILM SOLAR MODULE

(75) Inventors: Hermann Wagner, Jena (DE); Walter Psyk, Munich (DE); Peter Lechner, Haar (DE)

(73) Assignee: SCHOTT SOLAR AG, Mainz (DE)

(21) Appl. No.: 13/365,322

(22) Filed: Feb. 3, 2012

(30) Foreign Application Priority Data
Feb. 3, 2011 (DE) 102011010131.4-33

(51) Int. Cl. H01L 31/042

(52) U.S. Cl. 136/249

(57) ABSTRACT

A raw module is provided that includes a substrate, a front electrode layer, a semiconductor layer, and a rear electrode layer. The layers are separated by structuring trenches into sub cells, which are electrically connected in series in an interconnection direction. The module has a first separating region separating the module into two sub modules along a first separating line running in the interconnection direction. The separating region includes: a first and a second isolation trench running parallel to one another and on both sides of the first separating line in the interconnection direction; a third isolation trench extending from the first isolation trench at least as far as the first separating line but not as far as the second isolation trench; and a fourth isolation trench extending from the second isolation trench at least as far as the separating line but not as far as the first isolation trench.

### CROSS REFERENCE TO RELATED APPLICATIONS

This application claims benefit under 35 U.S.C. §119(a) of German Patent Application No. 10 2011 010 131.4-33, filed Feb. 3, 2011, the entire contents of which are incorporated herein by reference.

### BACKGROUND OF THE INVENTION

1. Field of the Invention

The invention relates to a raw module for producing a thin-film solar module, and to a thin-film solar module.

2. Description of Related Art

Alongside roof-top installations and large-area solar arrays in power station applications, thin-film solar modules are often also used in building façades, where reference is made to building-integrated photovoltaics. Thus, a thin-film solar module can, for example, be integrated into multiple glazing or else be part thereof. In comparison with a roof-top installation, the solar modules in this case generally have to be adapted in width and length to the façade elements in order to be able to utilize the largest possible proportion of the façade area present, and to achieve a uniform optical impression. Since the dimensions of the façade elements are generally constructionally predetermined, and different dimensions of the façade elements can occur even within a façade, solar modules having an individually adapted height and width are therefore required in the field of building-integrated photovoltaics.

In accordance with the prior art, thin-film solar modules are usually subdivided by parallel-offset structuring lines in front electrode layer, semiconductor layer and rear electrode layer into strip-shaped sub cells which are interconnected in series in an interconnection direction. In accordance with the prior art, it is possible to adapt the size of a solar module in the interconnection direction for example in the pitch of the cell width, wherein the raw module used for manufacturing the solar module is mechanically separated perpendicularly to the direction of the series interconnection prior to assembly. By way of example, the raw module can be separated by glass scribing and breaking or laser glass cutting and the outer sub cells can be used for contact-connection. By means of contact-connection with contact strips and encapsulation, the raw module is subsequently assembled to form a finished solar module.

Perpendicularly to the interconnection direction, however, the dimensioning of a solar module is predetermined by the length of the strip-shaped sub cells and can no longer be varied after the completion of the raw module. Therefore, for customer orders requiring adaptation of the module size in two directions, it is necessary in each case to create and manufacture solar modules with a design adapted to the customer requirements. In highly automated manufacture of solar modules which is optimized towards the mass production of a single module type having predetermined dimensions and a predetermined design, different module types and, in particular, individual small batches can, however, be produced only with high outlay on personnel and risk. Furthermore, high additional outlay arises since, for each solar module type, a design has to be developed and formulations, work plans, data sheets and test instructions have to be created.

A further disadvantage can be seen in the fact that the manufacture of corresponding customer-specific solar modules takes up a great deal of time since it is necessary firstly to manufacture customer-specific raw modules and then assemble them to form solar modules.

The object of the invention is to overcome the disadvantages of the prior art and to enable flexible production of thin-layer solar modules having variable dimensions in conjunction with the lowest possible manufacturing outlay.

### SUMMARY OF THE INVENTION

The invention provides a raw module for producing a thin-film solar module comprising a substrate and a layer system arranged on the substrate and comprising a front electrode layer, a semiconductor layer and a rear electrode layer, wherein the layers are separated by structuring trenches into sub cells and wherein the sub cells are electrically connected in series in an interconnection direction R.

The raw module according to the invention is characterized in that the raw module has at least one first separating region for separating the module into two sub modules along a first separating line, which runs in the interconnection direction R, wherein the first separating region comprises a first and a second isolation trench, which run parallel to one another and on both sides of the first separating line in the interconnection direction R, a third isolation trench, which extends from the first isolation trench at least as far as the first separating line but not as far as the second isolation trench, and a fourth isolation trench, which extends from the second isolation trench at least as far as the first separating line but not as far as the first isolation trench. In this case, the third and fourth isolation trenches preferably run perpendicular to the interconnection direction R.

As long as the raw module is not separated along the first separating line, the region between the first and second isolation trenches is photovoltaically active and can contribute to the current generation of the raw module. That is achieved by virtue of the fact that the generated current can flow in the region of the third and fourth isolation trenches in each case around the third and fourth isolation trenches, that is to say in each case via the non-interrupted region on the other side of the separating line. The entire cell area of the undivided raw module can therefore be utilized. By contrast, if the raw module is separated into two sub modules along the first separating line, then the third and fourth isolation trenches in each case bring about an interruption of the series interconnection of the sub cells, such that, on one sub module, the region lying between the first isolation trench and the first separating line is no longer photovoltaically active and, on the other sub module, the region lying between the second isolation trench and the first separating line is no longer photovoltaically active. The separation of the cell strip at the module edge, as is required for the further interconnection, is therefore effected particularly advantageously automatically by the process of the mechanical separation of the raw module into two sub modules. The raw module according to the invention can be processed to form a thin-film solar module having an area corresponding to the raw module or by separation along the first separating line to form a thin-film solar module having a smaller area, wherein edge regions which are photovoltaically inactive arise on the sub modules solely as a result of the mechanical separation of the raw module. The raw module according to the invention therefore has a universal and particularly functional design.

The raw module for producing a thin-film solar module should be understood to mean the intermediate product of a substrate provided with the photovoltaic functional layers, wherein the photovoltaic functional layers are generally subdivided into sub cells by structuring lines running parallel and are interconnected in series. However, a raw module is not yet contact-connected with electrical connecting means and not yet encapsulated. The subdivision of the photovoltaic layers into sub cells and the series interconnection thereof by means of structuring lines and methods for producing such structuring lines are known to the person skilled in the art and are of secondary importance within the scope of the present invention. A detailed explanation is therefore dispensed with.

The invention relates to raw modules for a wide variety of types of thin-film solar modules. By way of example, the raw module can have a superstrate configuration, wherein the incident light radiation is incident through a transparent substrate into the photovoltaic layers. Likewise, a substrate configuration can be involved, wherein the light radiation is incident into the photovoltaic layers from the opposite side to the substrate. Accordingly, the substrate can be a transparent substrate for example composed of glass or plastic, or else opaque substrates. The substrate can be present in the form of a plate or a flexible film. The raw module according to the invention preferably has a superstrate configuration, wherein a glass pane having a thickness of 1 mm to 10 mm is used as the substrate.

The front electrode layer can be, for example, a metallic layer or preferably a TCO layer (transparent conductive oxide) composed of a transparent conductive oxide such as, for example, ZnO:Al or SnO₂:F.

The semiconductor layer can consist of various semiconductor materials such as, for example, Si, Ge, CIGS (Cu—In—Ga—S/Se), Cd—Te or combinations thereof. It can furthermore have a p-n or p-i-n structure or a plurality of sub cells lying one above another and having a p-n and/or p-i-n structure. Preferably, an a-Si cell (amorphous silicon) or an a-Si/a-Si or a-Si/μc-Si tandem cell is involved.

By way of example, in the same way as the front electrode layer, the rear electrode layer can be a TCO layer composed of a transparent conductive oxide (TCO) such as, for example, ZnO:Al or SnO₂:F, a metallic layer or a multilayer system composed of TCO layers and metallic layers.

Furthermore, further layers can be arranged on the substrate, such as, for example, reflector layers, barrier layers, which prevent the intermixing of mutually adjacent layers e.g. as a result of diffusion, and also adhesion layers, which improve the mechanical cohesion of the layer system. In particular, a structured layer can be arranged between substrate and front electrode layer in order to improve the light trapping properties of the solar module.

It is clear to the person skilled in the art that the principle according to the invention can be applied to any thin-film solar cell present on a planar substrate, and so the cited embodiments of the raw module and of its constituents should be understood merely as examples.

A separating region should be understood to mean in each case the area region of the raw module between the first and second isolation trenches of this separating region which extends in the interconnection direction in a strip-shaped fashion over the raw module.

The separating line merely represents a fictitious line along which the raw module can potentially be mechanically broken up. It runs between the first and second isolation trenches, in which the layer system is removed, and parallel to the trenches. In the separating line itself, however, none of the functional layers has to be removed.

The first and second and also the third and fourth isolation trenches are in each case embodied in the form of a cutout in the layer system, comprising at least the function layers of front electrode, semiconductor layer and rear electrode layer. Both mechanical and laser-based methods for introducing the circumferential isolation trench are known to the person skilled in the art, and they can also be used for introducing these isolation trenches.

Preferred embodiments of the invention are explained in greater detail below. The first separating line preferably runs centrally between the first and second isolation trenches, and the two short isolation trenches run perpendicular to the first separating line. If the first separating line lies centrally between the first and second isolation trenches, then two sub modules having photovoltaically inactive edge strips having the same width are obtained by the separation of the raw module along the first separating line. However, the first separating line can be displaced from the centre also towards the first or second isolation trench, wherein the third and fourth isolation trenches are then preferably adapted in length. The third and fourth isolation trenches preferably run perpendicular to the first and second isolation trenches. Furthermore, the third and fourth isolation trenches preferably run in the transition region between an adjacent pair of series-interconnected sub cells, as a result of which the isolation trenches can be embodied in an optically inconspicuous fashion.

The first separating region preferably comprises further isolation trenches, each of the isolating trenches extending from the first or second isolation trench at least as far as the first separating line, but not as far as the respective other of the first and second isolation trenches, that is to say are embodied in a manner corresponding to the third and fourth isolation trenches. As a result of these further isolation trenches, the edge region lying between the first isolation trench and the first separating line is electrically interrupted after mechanical separation at a plurality of locations and in sections is completely electrically insulated from the contact-connection segments of the raw module. By means of corresponding positioning of at least two isolation trenches on opposite sides of the raw module, virtually the entire edge region of the sub module can be electrically insulated, thus giving rise to a circumferential insulated edge. Furthermore, a plurality of interruptions of the edge region can prevent high voltages from arising, since even the non-interconnected cell regions can build up corresponding voltages in the event of light incidence.

The raw module preferably comprises a circumferential isolation trench in the form of a cutout in the layer system, which trench extends circumferentially along the module edge and electrically insulates an active module area and an edge region from one another. The circumferential isolation trench is required in order to electrically insulate the voltage-carrying regions of the raw module from its surroundings. The circumferential isolation trench comprises at least the front electrode layer, the rear electrode layer and the semiconductor layer. In terms of its structure, it can correspond to the structuring trench in the separating region and also be introduced into the layer system using the same means which are known to the person skilled in the art. In the outer edge region, the layer system can be removed from the substrate, which is advantageous, in particular, if the thin-film solar module is intended to be encapsulated by lamination of a film. So-called edge coating removal methods known to the person skilled in the art can be used for this purpose.

Preferably, the first isolation trench and the second isolation trench of the first separating region extend over the entire module length in the interconnection direction or at least as far as the circumferential isolation trench, such that the active module area is divided into partial regions electrically insulated from one another.

In one preferred embodiment, the raw module comprises further separating regions having a structure in accordance with the first separating region, wherein the separating lines of the further separating regions are arranged parallel to the first separating line. With further preference, the separating regions are arranged at a regular distance d₂ and the distance d₂ is 10 millimeters (mm) to 500 mm, preferably 50 mm to 300 mm. The dimensioning of such a raw module can therefore be adapted in steps by mechanical separation along one of the separating lines of the separating regions.

The distance between the first and second isolation trenches of a separating region is preferably in each case 0.5 mm to 100 mm, and particularly preferably 4 mm to 50 mm. The distance between the first and second isolation trenches should correspond to an edge region of sufficient width after the separation along the separating line on both sub modules produced. Furthermore, the positioning accuracy and the cutting width should be taken into account during the mechanical separation of the raw module. Furthermore, the first isolation trench and second isolation trench of a separating region preferably in each case have the same distance d₁. The ratio of d₂ to d₁ is from 2 to 50, and preferably from 10 to 30.

In one preferred embodiment, the raw module is a semitransparent raw module which has transparency openings in the form of cutouts in the rear electrode layer and the semiconductor layer, such that part of the light incident on the raw module can be transmitted through the transparency openings. Semitransparent thin-film solar modules are used particularly in building-integrated photovoltaics, where a partial amount of the incident light radiation is intended to be used for illumination purposes in the building. Like the isolation trenches, the transparency openings consist in cutouts in the layer system. In contrast to the isolation trenches, where at least front electrode layer, semiconductor layer and rear electrode layer are removed, in the transparency openings the rear electrode layer and preferably also the semiconductor layer are removed. Possibilities for producing such transparency openings e.g. on the basis of laser removal methods, lift-off methods and the like are known to the person skilled in the art. Alongside the removal methods, there is also the possibility, in principle, of directly cutting out the transparency openings during the application of the layer system, which is possible for example with the aid of printing techniques. The relative area proportion of the total module area that is constituted by the transparency openings is generally between 5% and 50%. The transmittance of the raw module in the transparency openings is typically between 10% and 90%, such that a partial amount of the incident light radiation is allowed through for illumination purposes.

The transparency openings are preferably embodied in the form of transparency trenches running parallel in the interconnection direction R and are arranged at a regular distance d₃ and thus run parallel to the current flow direction, which has a positive effect on the electrical properties of the solar module. The transparency trenches preferably comprise a cutout in the rear electrode layer and a cutout in the semiconductor layer, wherein the cutout in the semiconductor layer can be embodied with a somewhat smaller width than the cutout in the semiconductor layer, as a result of which it is possible to reduce the risk of short circuits between front electrode layer and rear electrode layer in the region of the edges of the transparency trenches.

The distance between the first and second isolation trenches of a separating region d₁ preferably corresponds to a multiple of the distance between the transparency trenches d₃, wherein the first isolation trench and second isolation trench of a separating region are in each case arranged within a transparency trench. The isolation trenches arranged within the transparency trenches are positioned in an optically inconspicuous fashion. Furthermore, only the residual front electrode has to be severed within the transparency trenches. The cutout in the front electrode layer, which can be introduced by means of a laser, for example, preferably has a smaller width than the cutouts in semiconductor layer and rear electrode layer. Particularly preferably, the distance d₁ corresponds to double the value of the distance between the transparency trenches d₃, that is to say that the separating line of the semitransparent raw module runs in a transparency trench, and the first and second isolation trenches run in the transparency trenches adjacent on both sides.

In a further preferred embodiment, the raw module has complementary transparency trenches in the form of cutouts in the rear electrode layer and the semiconductor layer, which run perpendicular to the interconnection direction and are in each case formed in the transition region between two series-interconnected sub cells. Such complementary transparency trenches are known for example from DE 69228079 T2, page 14 and FIGS. 10 and 11. Methods for introducing the complementary transparency trenches are also familiar to the person skilled in the art. In comparison with the transparency trenches running in the interconnection direction, the complementary transparency trenches are preferably arranged in the transition regions between the series-interconnected sub cells and advantageously simultaneously replace the structuring line in the rear electrode layer.

Preferably, the raw module furthermore comprises contact-connection regions arranged on the first and last series-interconnected sub cells of each partial region. These cells are also designated as tapping cells. If the rear electrode layer consists of a metal layer, the first and last sub cells can be contact-connected directly on the rear electrode layer. However, in the contact-connection regions it is also possible to arrange further layers on the rear electrode layer, for example a nickel-vanadium layer, which prevents damage to the contact-connection regions of the thin-film cell.

The invention furthermore relates to a thin-film solar module comprising a raw module according to the invention. Thus, a thin-film solar module can comprise a single raw module according to the invention or else a sub module of a raw module according to the invention, which is mechanically separated for example along a separating line. Furthermore, a raw module according to the invention can also be shortened in the interconnection direction.

Likewise, a thin-film solar module according to the invention can comprise a first raw module and also at least one first sub module of a further raw module, wherein the first sub module can be obtained by separating the further raw module along a separating line, and wherein the first raw module has a first sub module embodied structurally identically to the first sub module. As a result, modules having a larger area than that of the raw module can also be produced.

Preferably, the first raw module and the first sub module are arranged alongside one another so as to give rise to the optical impression of a single raw module having a larger area than the first raw module. On account of the edge-insulated regions of the first raw module and of the first sub module, in this case it is not possible for undesired short circuits to occur in the region where the modules abut one another.

Preferably, such a thin-film solar module according to the invention furthermore comprises metallic contact-connection strips, wherein the contact-connection regions of the regions of the first raw module within the circumferential isolation line and the contact-connection regions of the regions of the first sub module within the circumferential isolation line and within the separating line are contact-connected by an electrically conductive connection to the contact-connection strip and the regions outside the circumferential isolation trench and the separating line are not contact-connected, as a result of which the edge regions of the first raw module and the first sub module act as insulating edge strips.

### BRIEF DESCRIPTION OF THE DRAWINGS

The invention is explained below by way of example on the basis of the following figures:

FIG. 1: plan view and cross-sectional view of a raw module according to the invention;

FIG. 2: plan view and cross-sectional view of a semitransparent embodiment of a raw module according to the invention; and

FIG. 3: plan view and cross-sectional view of a semitransparent raw module and of a further sub module.

### DETAILED DESCRIPTION

The figures illustrate schematic illustrations which are not to scale and serve merely for elucidating the invention. In particular, an illustration of the structuring lines which serve for dividing the layer system into sub cells and the series interconnection thereof has been dispensed with for reasons of clarity. The series interconnection also gives rise to the interconnection direction R, which is illustrated in the edge region of the figure with a direction arrow.

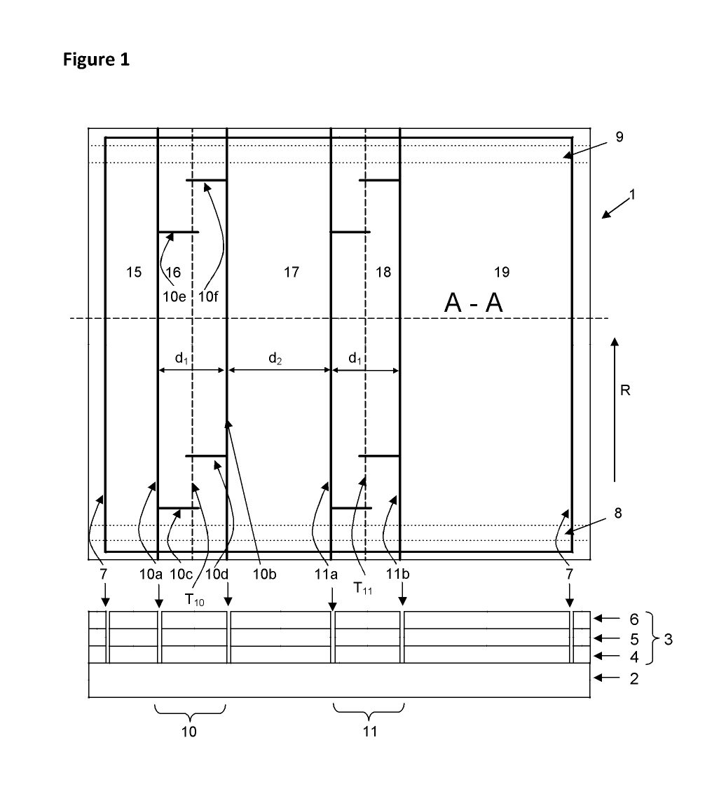

The upper partial figure in FIG. 1 schematically shows a raw module (1) according to the invention with a sectional plane A-A perpendicular to the interconnection direction R. The lower partial figure in FIG. 1 shows a schematic cross section in the sectional plane A-A, wherein the layer system (3) arranged on the substrate (2) has at least a front electrode layer (4), a semiconductor layer (5) and a rear electrode layer (6). The layer system is interrupted by the isolation trenches (10a, 10b, 11a, 11b), and subdivided into partial regions (15, 16, 17, 18, 19) electrically insulated from one another, wherein there is firstly the circumferential isolation line (7) and also the isolation lines of the separating regions (10, 11). The plane view illustrates by way of example two separating regions (10, 11) in which the raw module (1) can be separated in each case along a separating line (T₁₀, T₁₁). In the first separating region (10), there are arranged a first isolation trench (10a) and a second isolation trench (10b) in the interconnection direction, two isolation trenches (10c, 10e) extending from the first isolation trench (10a) as far as the separating line (T₁₀), and also two isolation trenches (10d, 10f) extending from the second isolation trench (10b) as far as the separating line (T₁₀). In the separating region (10), the current can flow in each case around the short separating line sections (10c, 10d, 10e, 10f) as long as the raw module (1) has not been separated along the separating line (T₁₀). Upon separation of the raw module along the separating line, by contrast, the short isolation trenches interrupt the current flow, with the result that the region between first isolation trench (10a) and separating line becomes an insulated edge region as a result of the mechanical separation. First and second isolation trenches are arranged in each case at a distance d₁, and the separating regions are arranged at a distance d₂. Typically, the distance d₁ is significantly less than the distance d₂, which is merely indicated qualitatively in the illustration, but is not to scale.

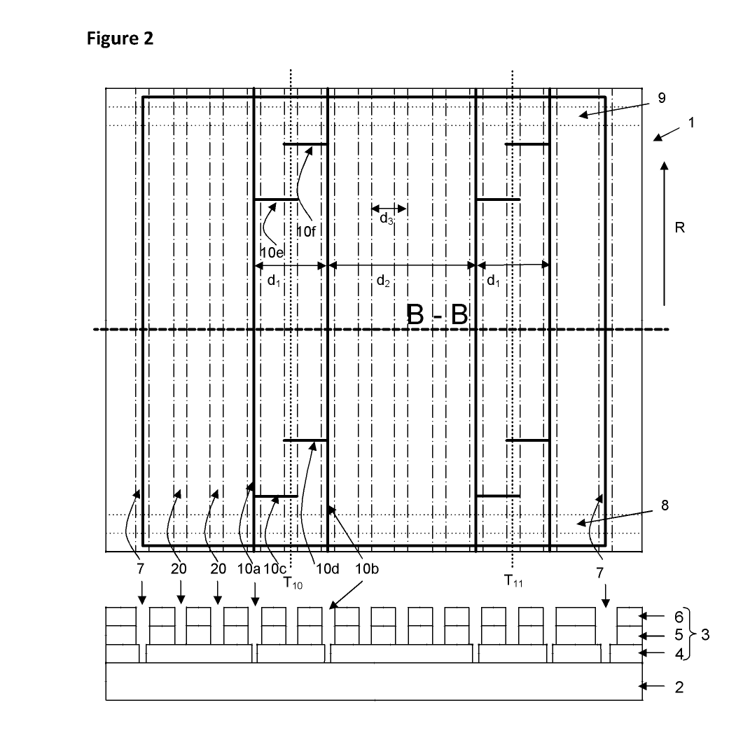

FIG. 2 illustrates a semitransparent raw module according to the invention. Supplementing the structures explained with reference to FIG. 1, the semitransparent raw module (1) has transparency trenches (20) in the interconnection direction R, in which at least the rear electrode layer (6) and preferably also the semiconductor layer (5) are cut out, as can be discerned in the cross-sectional illustration. The distance between the first isolation trench (10a) and second isolation trench (10b) corresponds precisely to double the distance between the transparency trenches d₃, and the isolation trenches (10a, 10b) are arranged within the transparency trenches, such that the separating line (T₁₀) runs precisely within the central transparency trench. Accordingly, exactly one region arranged between two transparency trenches becomes the insulated edge region upon the mechanical separation of the raw module along the separating line. Complementary transparency trenches can additionally be arranged perpendicularly to the transparency trenches illustrated, but the complementary transparency trenches, just like the structuring lines, are not illustrated for reasons of clarity.

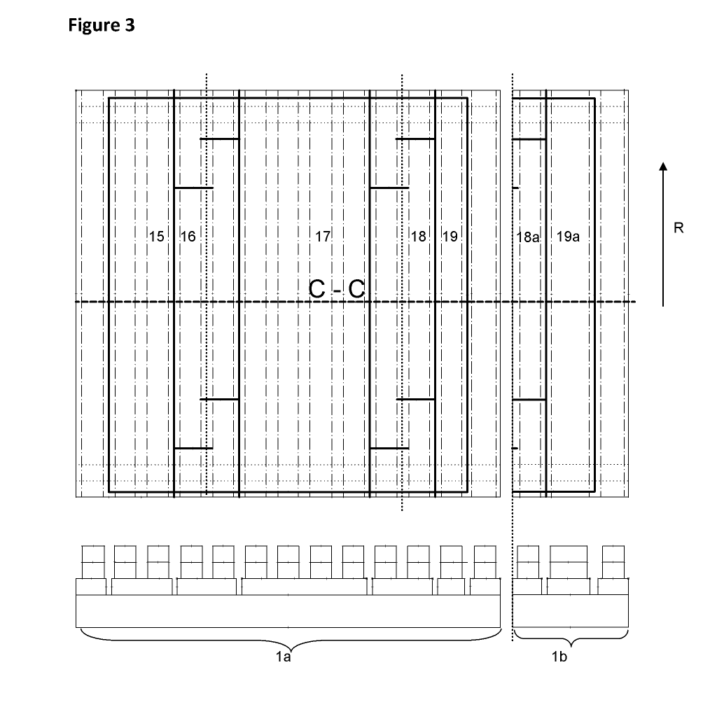

FIG. 3 shows a semitransparent first raw module (1a) according to the invention, and also a sub module (1b) of a further raw module of identical type, which is separated along a separating line and arranged alongside the first raw module (1a) in such a way that a large-area solar module arises.

The raw module according to the invention can be processed very flexibly to form thin-film solar modules having different lengths and widths, since it can be separated in addition to the adaptation known from the prior art in the direction of the series interconnection in each case in the separating regions and can thereby be adapted in magnitude in both dimensions. The maximum possible cell area is utilized photovoltaically, with the result that the raw module that can be divided firstly constitutes a raw module of high value for a thin-film solar module which comprises exactly one raw module.

By contrast, if thin-film solar modules of other sizes are required, a smaller sub module can be obtained by the separation of a raw module according to the invention, the sub module directly having an insulated edge region as a result of the mechanical separation along a separating line, with the result that the introduction of a further isolation trench can be dispensed with. Therefore, merely the electrical contact-connection and an encapsulation of the raw module also have to be effected.

Therefore, the raw module according to the invention can be used universally and replaces both a standard raw module for a thin-film solar module comprising exactly one raw module and specific raw modules for the production of a thin-film solar module having adapted dimensions.

The raw modules according to the invention can be produced as stock items and be kept in stock since they can be processed further flexibly to form thin-film solar modules having customer-specific dimensions. Thin-film solar modules having customer-specific dimensions can correspondingly be manufactured significantly more rapidly than is the case if the design of the raw module has to be adapted and corresponding customer-specific raw modules first have to be manufactured.

### LIST OF REFERENCE SYMBOLS

1 Raw module
1a First raw module
1b Sub module
2 Substrate
3 Layer system
4 Front electrode layer
5 Semiconductor layer
6 Rear electrode layer
7 Circumferential isolation trench
8 Contact-connection segment on first sub cell
9 Contact-connection segment on last sub cell
10 First separating region
10a,b First, second isolation trench
10c,d Third, fourth isolation trench
11,12 Further separating regions
15 . . . 19 Electrically insulated partial regions of the module
20 Transparency trench
R Interconnection direction
T₁₀ First separating line

What is claimed is:

1. A raw module for producing a thin-film solar module, comprising:
a substrate;
a layer system arranged on the substrate and comprising a front electrode layer, a semiconductor layer, and a rear electrode layer, wherein the front electrode, semiconductor and rear electrode layers are separated into sub cells by structuring trenches, the sub cells being electrically connected in series in an interconnection direction,
a first separating region separating the raw module into two sub modules along a first separating line, which runs in the interconnection direction, wherein the first separating region comprises a first isolation trench and a second isolation trench that run parallel to one another and on both sides of the first separating line in the interconnection direction R, a third isolation trench that extend from the first isolation trench at least as far as the first separating line, but not as far as the second isolation trench, and a fourth isolation trench that extends from the second isolation trench at least as far as the first separating line, but not as far as the first isolation trench.

2. The raw module according to claim 1, wherein the first separating line runs centrally between the first and second isolation trenches, and wherein the third and fourth isolation trenches run perpendicular to the interconnection direction.

3. The raw module according to claim 1, wherein the first separating region comprises further isolation trenches, each of the further isolating trenches extending from the first or second isolation trench at least as far as the first separating line, but not as far as the respective other of the first and second isolation trenches.

4. The raw module according to claim 1, furthermore comprising a circumferential isolation trench in the form of a cutout in the layer system, the circumferential trench extending circumferentially along an edge of the module and electrically insulating an active module area and an edge region from one another.

5. The raw module according to claim 4, wherein the first isolation trench and the second isolation trench extend at least as far as the circumferential isolation trench such that the active module area is divided into partial regions electrically insulated from one another.

6. The raw module according to claim 1, further comprising one or more further separating regions each separating the raw module into two sub modules along a separating line, which runs in the interconnection direction, and each comprising first, second, third and fourth isolation trenches, wherein the separating lines of the one or more further separating regions are arranged parallel to the first separating line.

7. The raw module according to claim 6, wherein the first separating region and the one or more further separating regions are arranged at a distance d₂from one another, wherein the distance d₂ is 10 mm to 500 mm.

8. The raw module according to claim 6, wherein the first and second isolation trenches of the first separating region or the one or more further separating regions are arranged at a distance d₁ from one another of 0.5 mm to 100 mm.

9. The raw module according to claim 6, wherein the first and second isolation trenches of the first separating region and the one or more further separating regions are arranged at a distance d₁ from one another.

10. The raw module according to claim 6, wherein the first and second isolation trenches of the first separating region or the one or more further separating regions are arranged at a distance d₂from one another, the first and second isolation trenches of the first separating region and the one or more further separating regions are arranged at a distance d₁ from one another, a ratio of the distant d₂to the distance d₁ is from 2 to 50.

11. The raw module according to claim 10, further comprising transparency openings in the form of cutouts in the rear electrode layer and the semiconductor layer such that at least part of incident light is transmitted through the transparency openings.

12. The raw module according to claim 11, wherein the transparency openings comprise parallel transparency trenches that run in the interconnection direction and are arranged at a distance d₃from one another.

13. The raw module according to claim 12, wherein the distance d₁ corresponds to a multiple of the distance d₃

14. The raw module according to claim 13, wherein the first and second isolation trenches of the first separating region and the at least one further separating regions are in each case arranged within the parallel transparency trenches.

15. The raw module according to claim 13, wherein multiple comprises 2 such that the distance d₁ corresponds to double the distance d₃.

16. The raw module according to claim 12, further comprising complementary transparency trenches in the form of cutouts in the rear electrode layer and the semiconductor layer, which run perpendicular to the interconnection direction and are in each case formed in the transition region between two sub cells.

17. The raw module according to claim 1, further comprising contact-connection regions on the sub cells.

18. A thin-film solar module comprising the raw module according to claim 1.

19. The thin-film solar module according to claim 18, further comprising at least one first sub module of a further raw module, wherein the first sub module is separated from the further raw module along a separating line, and wherein the raw module has a sub module embodied structurally identically to the first sub module.

20. The thin-film solar module according to claim 19, wherein the raw module and the first sub module are arranged alongside one another so as to give rise to an optical impression of a single raw module having a larger area than the raw module.
